(19) United States
(12) Patent Application Publication
(10) Pub. No.: US 2025/0050463 A1
(43) Pub. Date: Feb. 13, 2025

(54) PAD CONDITIONER

(71) Applicant: SAESOL Diamond Ind. Co., Ltd., Ansan-si, Gyeonggi-do (KR)

(72) Inventor: Sung Goo LEE, Siheung-si Gyeonggi-do (KR)

(73) Assignee: SAESOL Diamond Ind. Co., Ltd., Ansan-si, Gyeonggi-do (KR)

(21) Appl. No.: 18/711,643

(22) PCT Filed: Dec. 2, 2022
(86) PCT No.: PCT/KR2022/019465

§ 371 Date: May 20, 2024

(30) Foreign Application Priority Data
Jul. 20, 2022 (KR) 10-2022-0089262

(51) Int. Cl. B24B 53/017

(52) U.S. Cl. CPC B24B 53/017

(57) ABSTRACT

A pad conditioner for dressing the surface of a CMP pad according to an embodiment of the present invention comprises: a substrate; and a plurality of protrusion members provided on the substrate. Each of the protrusion members may include: a cutting part that cuts the pad, a roughness control part that supports the cutting part and limits the indentation depth of the cutting part; and a body part that protrudes from the substrate and supports the roughness control part.

### TECHNICAL FIELD

The present invention relates to a pad conditioner, and more specifically, to a pad conditioner for a chemical mechanical polishing (CMP) device used in a planarization operation of a wafer.

### BACKGROUND ART

A chemical mechanical polishing (CMP) device is a polishing device for obtaining the flatness of semiconductor wafers, and polishes the wafers by rotationally rubbing the wafers against a pad while supplying a slurry containing a polishing compound and determines polishing performance according to a surface state of the pad and various factors.

As a CMP polishing process progresses, the polishing ability of the wafer is reduced due to the slurry adsorbed on the pad, and thus a conditioner is needed to restore the performance of the pad, and a conditioning operation of restoring planarization and performance by cutting a pad surface on which the slurry is adsorbed using the conditioner is performed.

However, since conventional conditioners could not control the roughness formed on the pad surface in the conditioning process, there has been a problem in that the slurry is hardened by plastic deformation and scratches are formed on a wafer surface due to protruded portions.

In addition, due to the miniaturization and high stacking of semiconductor processes, the CMP polishing process requires a higher level of wafer polishing uniformity and performance deviation between products than those in the past, and the development for a conditioner technology capable of meeting such a demand is required.

### DISCLOSURE

### Technical Problem

The present invention has been made in efforts to solve the problems and is directed to providing a pad conditioner capable of minimizing roughness generated during a conditioning operation and reducing a performance deviation between products.

The object of the present invention is not limited to the above-described object, and other objects that are not mentioned will be able to be clearly understood by those skilled in the art from the following description.

### Technical Solution

A pad conditioner configured to dress a surface of a chemical mechanical polishing (CMP) pad according to an embodiment of the present invention may include a substrate, and a plurality of protruding members provided on the substrate, wherein the protruding member may include a cutting part that cuts the pad, a roughness control part that supports the cutting part and restricts an indentation depth of the cutting part, and a body part that protrudes from the substrate to support the roughness control part.

The roughness control part may extend horizontally from an upper surface of the body part so that an upper surface of the roughness control part is parallel to the upper surface of the body part, and the cutting part may extend vertically from the upper surface of the roughness control part so that an upper end surface of the cutting part is formed to have a step difference with the upper surface of the roughness control part.

A width of the roughness control part may be the same as a width of the cutting part, and both side surfaces of the cutting part in a width direction may have a structure that is consecutively connected to both side surfaces of the roughness control part in the width direction, and a length of the roughness control part may be larger than a length of the cutting part, and both side surfaces of the cutting part in a longitudinal direction may have a structure that is disposed on the upper surface of the roughness control part and forms a step difference with both side surfaces of the roughness control part in the longitudinal direction.

A height of the cutting part may be formed to be at least the same as or larger than a height of the roughness control part.

A length of the roughness control part may be the same as a length of the body part, and both side surfaces of the roughness control part in a longitudinal direction may have a structure that is consecutively connected to both side surfaces of the body part in the longitudinal direction, and a width of the roughness control part may be smaller than a width of the body part, and both side surfaces of the roughness control part in a width direction may have a structure which is disposed on the upper surface of the body part to have a step difference with both side surfaces of the body part in the width direction.

The pad conditioner may further include a coating layer formed on a surface of the protruding member.

The protruding members may have different lengths, and a protruding member with a relatively small length and a protruding member with a relatively large length may be disposed by being mixed at a set ratio.

### Advantageous Effects

According to the embodiments of the present invention, it is possible to provide the pad conditioner capable of minimizing the roughness generated during the conditioning operation and reducing the performance deviation between products.

The effects of the present invention are not limited to the above-described effects, and other effects that are not mentioned will be able to be clearly understood by those skilled in the art from the following description.

### DESCRIPTION OF DRAWINGS

FIG. 1 is a plan view schematically showing a pad conditioner according to one embodiment of the present invention.

FIG. 2 is a perspective view schematically showing a protruding member in the pad conditioner of FIG. 1.

FIGS. 3A, 3B, and 3C are respectively a plan view, side view, and front view schematically showing the protruding member of FIG. 2.

FIGS. 4A and 4B are respectively a side view and front view schematically showing a state in which a coating layer is formed on the protruding member of FIGS. 3B and 3C.

FIG. 5 is a perspective view schematically showing another embodiment of the protruding member of FIG. 2.

FIGS. 6A and 6B are each plan views schematically showing a pad conditioner according to another embodiment of the present invention.

### MODE FOR INVENTION

Since the present invention may have various changes and various embodiments, specific embodiments are illustrated and described in the accompanying drawings. However, it should be understood that it is not intended to limit specific embodiments, and it should be understood to include all modifications, equivalents, and substitutes included in the spirit and scope of the present disclosure. Terms including ordinal numbers such as first or second may be used to describe various components, but the components are not limited by the terms. The terms are used only for the purpose of distinguishing one component from another. For example, a second component may be referred to as a first component, and similarly, the first component may also be referred to as the second component without departing from the scope of the present invention. The term “and/or” includes a combination of a plurality of related listed items or any of the plurality of related listed items.

When a first component is described as being “connected” or “coupled” to a second component, it should be understood that the first component may be directly connected or coupled to the second component or a third component may be present therebetween. On the other hand, when the first component is described as being “directly connected” or “directly coupled” to the second component, it should be understood that the third component is not present therebetween.

In the description of the embodiment, in a case in which one component is described as being formed “on (above)” or “below (under)” another component, “on (above)” or “below (under)” includes both a case in which two components are in direct contact with each other or a case in which one or more other components are disposed between the two components. In addition, when described as “on (above)” or “below (under),” it may include the meaning of not only an upward direction but also a downward direction with respect to one component.

The terms used in the application are only used to describe specific embodiments and are not intended to limit the present invention. The singular expression includes the plural expression unless the context clearly dictates otherwise. In the application, it should be understood that terms “include” and “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof.

Unless defined otherwise, all terms used herein, including technical or scientific terms, have the same meaning as commonly understood by those skilled in the art to which the present invention pertains. The terms defined in a generally used dictionary should be construed as meanings that match with the meanings of the terms from the context of the related technology and are not construed as an ideal or excessively formal meaning unless clearly defined in this application.

Hereinafter, embodiments will be described in detail with reference to the accompanying drawings, and the same or corresponding components are denoted by the same reference numeral regardless of the reference numerals, and overlapping descriptions thereof will be omitted.

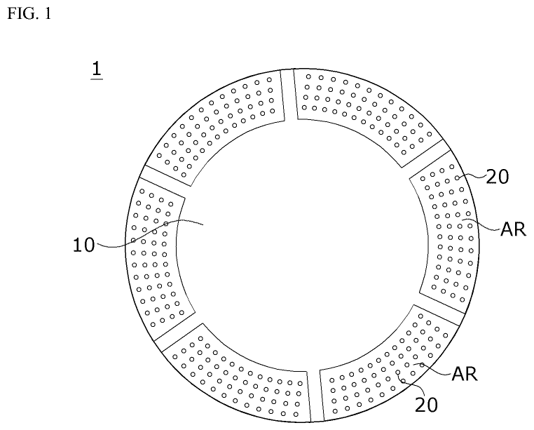

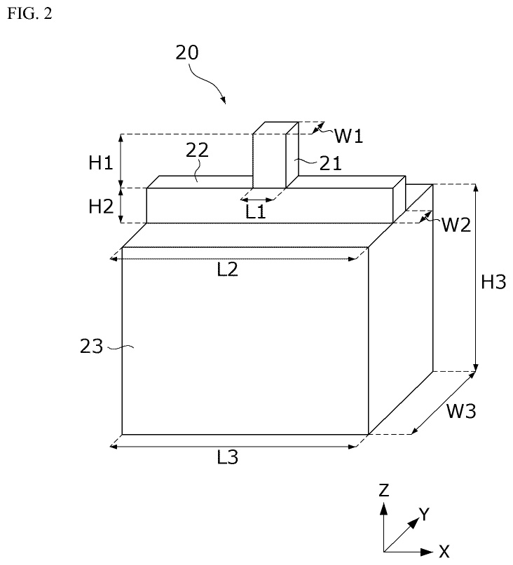

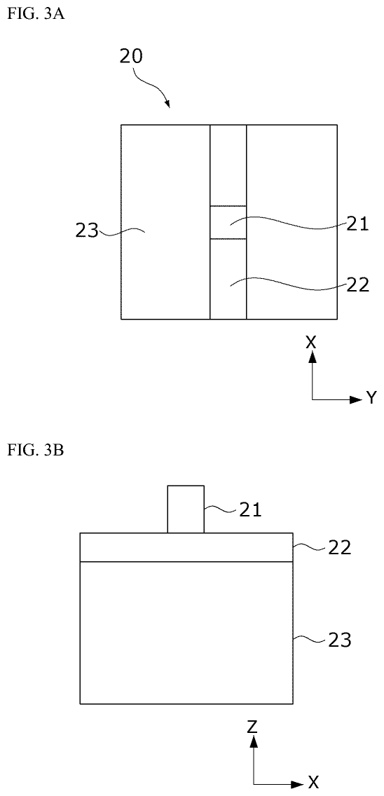

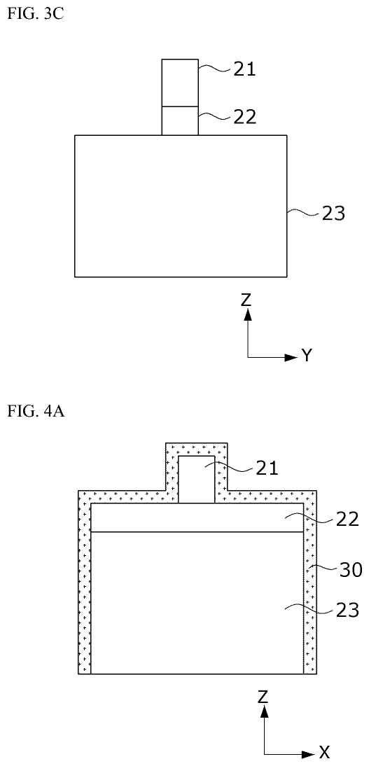

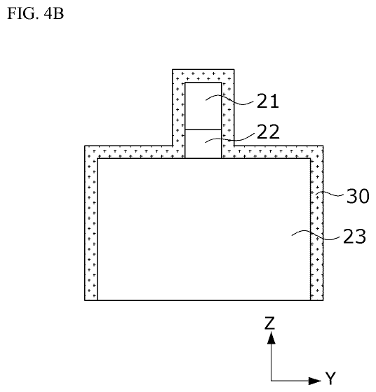

FIG. 1 is a plan view schematically showing a pad conditioner according to one embodiment of the present invention, FIG. 2 is a perspective view schematically showing a protruding member in the pad conditioner of FIG. 1, FIGS. 3A, 3B, and 3C are respectively a plan view, side view, and front view schematically showing the protruding member of FIG. 2, and FIGS. 4A and 4B are respectively a side view and front view schematically showing a state in which a coating layer is formed on the protruding member of FIGS. 3B and 3C.

Referring to the drawings, a pad conditioner 1 according to an embodiment of the present invention may include a substrate 10 and a plurality of protruding members 20 arranged to protrude from the substrate 10. In addition, the pad conditioner 1 may further include a coating layer 30 formed on a surface of the protruding member 20.

The substrate 10 may be manufactured to have a disk shape using a material such as metal, an alloy, or ceramic with high strength and hardness. In one embodiment, the substrate 10 may be made of a tungsten carbide.

The protruding member 20 for cutting may be provided on one surface of the substrate 10, and a motor (not shown) for rotating the pad conditioner 1 may be connected to the other surface of the substrate 10.

The protruding member 20 may be formed to protrude upward from the planar substrate 10.

The protruding member 20 may have a surface on which the coating layer 30 is formed and may be in contact with a surface of the CMP pad by pressing in a state in which the coating layer 30 is formed to cut a pad surface as the substrate 10 rotates.

The coating layer 30 may include polishing particles with high hardness, such as diamond, and may be formed on the surface of the protruding member. The coating layer 30 is formed by coating the surface of the protruding member 20 with diamond particles having a diamond grain size of nano (nm) or micron (μm) by chemical vapor deposition (CVD). In an embodiment, the coating layer 30 may be formed in a thickness of about 10 μm.

Since the coating layer 30 is the same as a diamond coating layer formed in a general CVD-type CMP pad conditioner, detailed description thereof will be omitted.

Hereinafter, the protruding member 20 will be described in more detail.

The protruding members 20 may be disposed to be spaced apart from each other at a constant distance. In an embodiment, a distance between the protruding members 20 may range from about 300 to 1500 μm.

The protruding member 20 may be disposed along an edge perimeter of an edge area of the substrate 10. In this case, the protruding member 20 may be formed in a plurality of divided areas AR on the substrate 10. Of course, the protruding member 20 may be provided over the overall area of the substrate 10 or provided radially.

As shown in FIG. 2, the protruding member 20 may be provided as a protruding structure with an overall square shape.

The protruding member 20 may include a cutting part 21 for cutting the pad, a roughness control part 22 for supporting the cutting part 21 and restricting an indentation depth of the cutting part 21, and a body part 23 protruding from the substrate 10 and for supporting the roughness control part 22.

In an embodiment, the cutting part 21, the roughness control part 22, and the body part 23 may be formed integrally. In addition, the protruding member 20 may be made of the same material as that of the substrate 10.

The body part 23 is formed to protrude upward from the surface of the substrate at a predetermined height, the roughness control part 22 is formed to protrude upward from an upper surface of the body part 23, and the cutting part 21 is formed to protrude upward from an upper surface of the roughness control part 22.

Here, since an area of the upper surface of the body part 23 is formed to be larger than an area of the upper surface of the roughness control part 22 and the area of the upper surface of the roughness control part 22 is formed to be larger than an area of the upper surface of the cutting part 21, the protruding member 20 may be formed in a structure forming a three-stage stepped structure with respect to the substrate 10.

The body part 23 may have a height H3 ranging from about 50 μm to 100 μm. When the height H3 is smaller than 50 μm, there is a problem that a slurry generated in the cutting process is fused due to insufficient separation distance from the pad, and when the height H3 exceeds 100 μm, there may be a problem that the roughness control unit 22 and the cutting part 21 that are formed above the body part 23 may not be stably supported by a shear force.

The body part 23 may have an overall quadrangular pillar shape. In an embodiment, the body part 23 may be formed to have a width W3 and a length L3 ranging from about 80 μm to 160 μm. Such a range may be set in consideration of an aspect ratio according to the height H3.

The roughness control part 22 may extend horizontally from the upper surface of the body part 23 and be formed so that the upper surface of the roughness control part 22 is parallel to the upper surface of the body part 23. In other words, the roughness control part 22 may be provided to protrude in a structure extending as much as a length L3 of the body part 23 from a center of the upper surface of the body part 23.

Referring to the drawings, a length L2 of the roughness control part 22 may be formed to be the same as the length L3 of the body part 23, and thus both side surfaces of the roughness control part 22 in a longitudinal direction may have a structure that is consecutively connected to both side surfaces of the body part 23 in the longitudinal direction. In an embodiment, the roughness control part 22 may have the length L2 ranging from about 80 μm to 160 μm.

In addition, a width W2 of the roughness control part 22 may be formed to be smaller than the width W3 of the body part 23, and thus both side surfaces of the roughness control part 22 in a width direction may be formed on the upper surface to have a step difference with both side surfaces of the body part 23 in the width direction without connection. In an embodiment, the roughness control part 22 may be formed to have the width W2 ranging from about 20 μm to 70 μm.

In addition, the roughness control part 22 may have a height H2 ranging from about 5 μm to 20 μm. When the height H2 is smaller than 5 μm, a function of adjusting the roughness of the pad may not be sufficiently performed, and when the height H2 exceeds 20 μm, there may be a problem that the cutting part 21 may not be sufficiently supported by the shear force applied to the cutting part 21 formed above the roughness control part 22.

In the present embodiment, the longitudinal direction is defined as corresponding to an X-axis direction of the coordinate axis, the width direction is defined as corresponding to a Y-axis direction, and a vertical direction is defined as corresponding to a Z-axis direction.

Meanwhile, the cutting part 21 may extend in the vertical direction from the upper surface of the roughness control part 22 and may be formed so that an upper end surface of the cutting part 21 may be formed to have a step difference in parallel to the upper surface of the roughness control part 22.

Specifically, the width W1 of the cutting part 21 may be formed to be the same as the width W2 of the roughness control part 22, and thus both side surfaces of the cutting part 21 in the width direction may have a structure that is consecutively connected to the both side surfaces of the roughness control part 22 in the width direction. In an embodiment, the cutting part 21 may be formed to have the width W1 ranging from about 20 μm to 70 μm.

In addition, the length L1 of the cutting part 21 may be formed to be smaller than the length L2 of the roughness control part 22, and thus the both side surfaces of the cutting part 21 in the longitudinal direction may be disposed on the upper surface of the roughness control part 22 to have a step difference with the both side surfaces of the roughness control part 22 in the longitudinal direction without connection. In an embodiment, the cutting part 21 may have the length L1 ranging from about 20 μm to 70 μm.

In addition, a height H1 of the cutting part 21 may be formed to be at least the same as or larger than the height H2 of the roughness control part 22. In an embodiment, the cutting part 21 may be formed to have the height H1 ranging from about 15 μm to 50 μm.

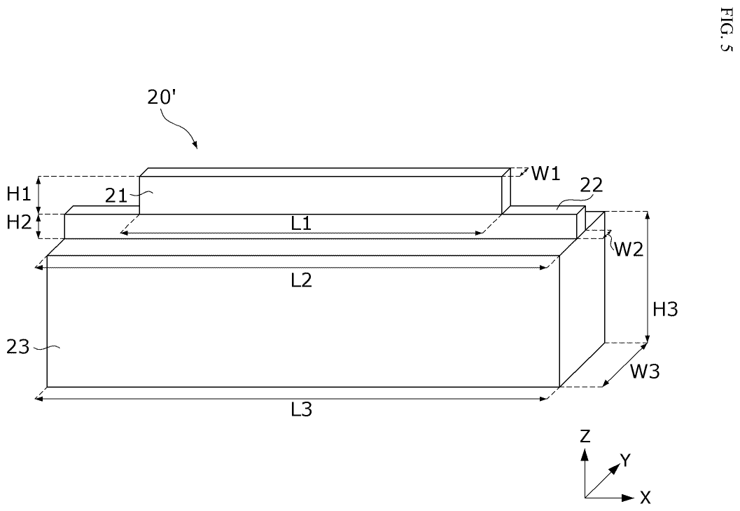

FIG. 5 schematically shows another embodiment of the protruding member.

As shown in FIG. 5, a protruding member 20′ may include the body part 23, the roughness control part 22 disposed on the body part 23, and the cutting part 21 disposed on the roughness control part. In addition, unlike the protruding member 20 of FIG. 3, the protruding member 20′ may have a rectangular shape extending in the longitudinal direction.

Referring to the drawing, the body part 23 of the protruding member 20′ may be formed in a rectangular shape with the length L3 of about 340 μm and the width W3 of about 100 μm. The height H3 may be formed in the range of about 50 μm to 100 μm.

In addition, the roughness control part 22 may be formed to have the length L2 of 340 μm to correspond to the length L3 of the body part 23. In addition, the roughness control part 22 may be formed to have the width W2 ranging about 20 μm to 70 μm and the height H2 ranging from 5 μm to 20 μm.

In addition, the cutting part 21 may be formed to have the length L1 of about 240 μm. In addition, the cutting part 21 may be formed to have the width W1 ranging about 20 μm to 70 μm and the height H1 ranging from 15 μm to 50 μm.

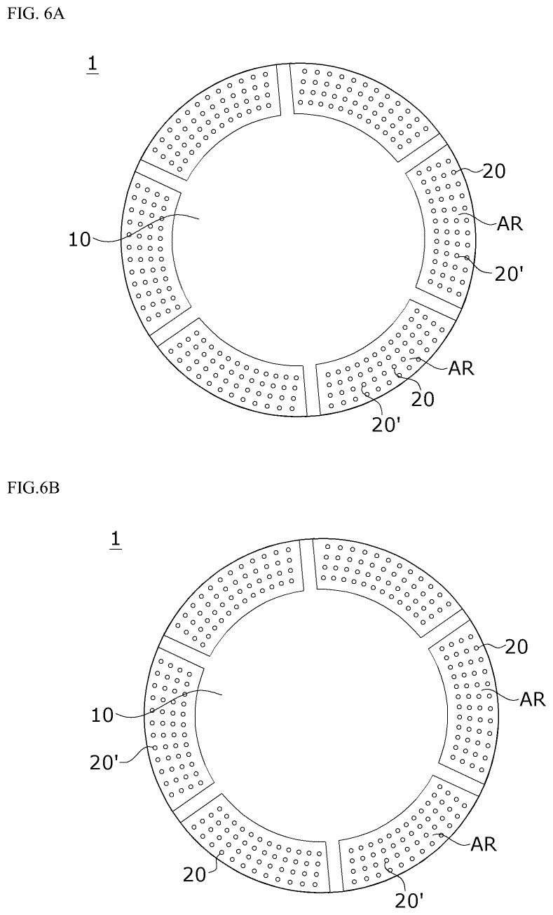

FIG. 6 schematically shows a pad conditioner according to another embodiment of the present invention.

In an embodiment, as shown in FIG. 6A, when the protruding members 20 and 20′ with different shapes (lengths) are disposed, the square-shaped protruding member 20 and the rectangular-shaped protruding member 20′ may be disposed by being mixed at a set ratio in each area AR. In other words, the protruding member 20 with a relatively small length and the protruding member 20′ with a relatively large length may be disposed by being mixed at the set ratio. In this case, the ratio setting may be changed in various ways according to the type of pad.

In addition, as shown in FIG. 6B, the shapes of the protruding members 20 and 20′ provided in each area AR may be provided to be different from the protruding members 20 and 20′ provided in adjacent areas AR. In other words, when the square-shaped protruding member 20 is provided in one area AR, the rectangular-shaped protruding member 20′ may be configured to be provided in another adjacent area AR.

Therefore, when the conditioning operation is performed on various types of pads, it is possible to obtain an overall uniform operation effect without being significantly affected by the physical characteristics of the corresponding pad.

To secure the high wafer polishing ability and the ability to maintain the same, it is necessary to increase the cutting amount of the pad. However, as the cutting amount of the pad increases, the roughness of the pad also tends to increase, and in this process, the pad is hardened due to inelastic deformation and fusion reaction with the slurry, resulting in the formation of protruded portions. The protruded portions increase the possibility of forming scratches on the wafer surface.

The protruding member 20 according to the embodiment of the present invention includes the roughness control part 22 between the cutting part 21 for cutting the pad and the body part 23 for supporting the cutting part 21 to control the roughness of the pad.

Specifically, the roughness control part 22 may restrict the indentation depth of the cutting part 21 to maintain a constant indentation depth. In addition, it is possible to cancel a height H1 deviation of the cutting part 21 that may be caused by processing errors. Therefore, it is possible to reduce a performance deviation between products due to tip area errors and the height deviation that occur during processing in conventional structures.

In addition, the roughness control part 22 may control the entirety of the roughness of the pad to be reduced by pushing and pressing protruded portions near the cutout portion of the pad with an effective pressure after cutting is performed, and thus it is possible to effectively reduce the frequency of the occurrence of the wafer scratches.

Although the present invention has been described above with reference to embodiments, those skilled in the art may understand that the present invention may be modified and changed in any of various ways without departing from the spirit and scope of the present invention. In addition, the differences related to the modifications and changes should be construed as being included in the scope of the present invention as defined in the appended claims.

1. A pad conditioner configured to dress a surface of a chemical mechanical polishing (CMP) pad, comprising:
a substrate; and
a plurality of protruding members provided on the substrate,
wherein the protruding member includes a cutting part that cuts the pad, a roughness control part that supports the cutting part and restricts an indentation depth of the cutting part, and a body part that protrudes from the substrate to support the roughness control part.

2. The pad conditioner of claim 1, wherein the roughness control part extends horizontally from an upper surface of the body part so that an upper surface of the roughness control part is parallel to the upper surface of the body part, and
the cutting part extends vertically from the upper surface of the roughness control part so that an upper end surface of the cutting part is formed to have a step difference with the upper surface of the roughness control part.

3. The pad conditioner of claim 2, wherein a width of the roughness control part is the same as a width of the cutting part, and both side surfaces of the cutting part in a width direction have a structure that is consecutively connected to both side surfaces of the roughness control part in the width direction, and
a length of the roughness control part is larger than a length of the cutting part, and both side surfaces of the cutting part in a longitudinal direction have a structure that is disposed on the upper surface of the roughness control part and forms a step difference with both side surfaces of the roughness control part in the longitudinal direction.

4. The pad conditioner of claim 2, wherein a height of the cutting part is formed to be at least the same as or larger than a height of the roughness control part.

5. The pad conditioner of claim 2, wherein a length of the roughness control part is the same as a length of the body part, and both side surfaces of the roughness control part in a longitudinal direction have a structure that is consecutively connected to both side surfaces of the body part in the longitudinal direction, and
a width of the roughness control part is smaller than a width of the body part, and both side surfaces of the roughness control part in a width direction have a structure which is disposed on the upper surface of the body part to have a step difference with both side surfaces of the body part in the width direction.

6. The pad conditioner of claim 1, further comprising a coating layer formed on a surface of the protruding member.

7. The pad conditioner of claim 1, wherein the protruding members have different lengths, and a protruding member with a relatively small length and a protruding member with a relatively large length are disposed by being mixed at a set ratio.
